(19) United States
(12) Patent Application Publication
(10) Pub. No.: US 2020/0339415 A1
(43) Pub. Date: Oct. 29, 2020

(54) ARTIFICIAL MATERIAL

(71) Applicant: Elwha LLC, Bellevue, WA (US)

(72) Inventors: Daniel Arnitz, Seattle, WA (US); Patrick Bowen, Durham, NC (US); Seyedmohammadreza Faghih Imani, Durham, NC (US); Joseph Hagerty, Seattle, WA (US); Roderick A. Hyde, Redmond, WA (US); Edward K.Y. Jung, Las Vegas, NV (US); Guy Shlomo Lipworth, Seattle, WA (US); Nathan P. Myhrvold, Bellevue, WA (US); David R. Smith, Durham, NC (US); Clarence T. Tegreene, Mercer Island, WA (US); Yaroslav A. Urzhumov, Bellevue, WA (US); Lowell L. Wood, JR., Bellevue, WA (US)

(21) Appl. No.: 16/872,253

(22) Filed: May 11, 2020

Related U.S. Application Data
(63) Continuation of application No. PCT/US2018/060784, filed on Nov. 13, 2018.
(60) Provisional application No. 62/587,286, filed on Nov. 16, 2017.

(51) Int. Cl. B81B 7/04

(52) U.S. Cl. CPC B81B 7/04; B81B 2207/07; B81B 2207/056; B81B 2203/0361

(57) ABSTRACT

An apparatus includes a base having a first surface and an array of pillars. Each pillar of the array of pillars includes (i) a first end attached to the first surface of the base; (ii) a second end having an electric charge retention portion; (iii) a physical separation from adjacent pillars of the array of pillars; and (iv) an electrical conductor configured to electrically connect the electric charge retention portion with a bus structure. The bus structure is configured to addressably connect with the electrical conductor of each respective pillar of the array of pillars.

### CROSS REFERENCE TO RELATED APPLICATIONS

This application is a continuation of PCT App. No. PCT/US2018/060784, filed 13 Nov. 2018, for “ARTIFICIAL MATERIAL,” which claims priority to U.S. Provisional App. No. 62/587,286, filed 16 Nov. 2017. The subject matter of each of the aforementioned applications is incorporated herein by reference to the extent such subject matter is not inconsistent herewith.

### SUMMARY

For example, and without limitation, an embodiment of the subject matter described herein includes a system.

The foregoing summary is illustrative only and is not intended to be in any way limiting.

In addition to the illustrative aspects, embodiments, and features described above, further aspects, embodiments, and features will become apparent by reference to the drawings and the following detailed description.

### BRIEF DESCRIPTION OF THE FIGURES

FIG. 1 illustrates an embodiment of an apparatus.

FIG. 2A illustrates an embodiment of a system including an apparatus and a pillar array manager circuit.

FIG. 2B illustrates an embodiment of a system including an apparatus and an atomic force microscope.

FIG. 3 illustrates an embodiment of an operational flow that can be implemented using the system of FIG. 2B.

FIG. 4 illustrates an embodiment of a system including an apparatus and an acoustic wave detection circuit.

FIG. 5 illustrates an embodiment of an operational flow that can be implemented using the system of FIG. 4.

FIG. 6 illustrates an embodiment of a system including an apparatus and a wave propagation controller circuit.

FIG. 7 illustrates an embodiment of an operational flow that can be implemented using the system of FIG. 6.

FIG. 8 illustrates an embodiment of a system including an apparatus and an acoustic wave detection circuit.

FIG. 9 illustrates an embodiment of an operational flow that can be implemented using the system of FIG. 8.

FIG. 10 illustrates an embodiment of a nano-positioning device including an actuator apparatus and a nano-positioning controller circuit.

FIG. 11 illustrates an embodiment of an operational flow that can be implemented using the system of FIG. 10.

FIG. 12 illustrates an embodiment of a system including an apparatus and a base parameter manager circuit.

FIG. 13 illustrates an embodiment of an operational flow that can be implemented using the system of FIG. 12.

FIG. 14 illustrates an embodiment of a system including an apparatus and a base parameter manager circuit.

FIG. 15 illustrates an embodiment of an operational flow that can be implemented using the system of FIG. 14.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

Those having skill in the art will recognize that the state of the art has progressed to the point where there is little distinction left between hardware, software, and/or firmware implementations of aspects of systems; the use of hardware, software, and/or firmware is generally (but not always, in that in certain contexts the choice between hardware and software can become significant) a design choice representing cost vs. efficiency tradeoffs. Those having skill in the art will appreciate that there are various implementations by which processes and/or systems and/or other technologies described herein can be effected (e.g., hardware, software, and/or firmware), and that the preferred implementation will vary with the context in which the processes and/or systems and/or other technologies are deployed. For example, if an implementer determines that speed and accuracy are paramount, the implementer may opt for a mainly hardware and/or firmware implementation; alternatively, if flexibility is paramount, the implementer may opt for a mainly software implementation; or, yet again alternatively, the implementer may opt for some combination of hardware, software, and/or firmware. Hence, there are several possible implementations by which the processes and/or devices and/or other technologies described herein may be effected, none of which is inherently superior to the other in that any implementation to be utilized is a choice dependent upon the context in which the implementation will be deployed and the specific concerns (e.g., speed, flexibility, or predictability) of the implementer, any of which may vary. Those skilled in the art will recognize that optical aspects of implementations will typically employ optically-oriented hardware, software, and or firmware.

In some implementations described herein, logic and similar implementations may include software or other control structures suitable to implement an operation. Electronic circuitry, for example, may manifest one or more paths of electrical current constructed and arranged to implement various logic functions as described herein. In some implementations, one or more media are configured to bear a device-detectable implementation if such media hold or transmit a special-purpose device instruction set operable to perform as described herein. In some variants, for example, this may manifest as an update or other modification of existing software or firmware, or of gate arrays or other programmable hardware, such as by performing a reception of or a transmission of one or more instructions in relation to one or more operations described herein. Alternatively or additionally, in some variants, an implementation may include special-purpose hardware, software, firmware components, and/or general-purpose components executing or otherwise invoking special-purpose components. Specifications or other implementations may be transmitted by one or more instances of tangible transmission media as described herein, optionally by packet transmission or otherwise by passing through distributed media at various times.

Alternatively or additionally, implementations may include executing a special-purpose instruction sequence or otherwise invoking circuitry for enabling, triggering, coordinating, requesting, or otherwise causing one or more occurrences of any functional operations described below. In some variants, operational or other logical descriptions herein may be expressed directly as source code and compiled or otherwise invoked as an executable instruction sequence. In some contexts, for example, C++ or other code sequences can be compiled directly or otherwise implemented in high-level descriptor languages (e.g., a logic-synthesizable language, a hardware description language, a hardware design simulation, and/or other such similar mode(s) of expression). Alternatively or additionally, some or all of the logical expression may be manifested as a Verilog-type hardware description or other circuitry model before physical implementation in hardware, especially for basic operations or timing-critical applications. Those skilled in the art will recognize how to obtain, configure, and optimize suitable transmission or computational elements, material supplies, actuators, or other common structures in light of these teachings.

In a general sense, those skilled in the art will recognize that the various embodiments described herein can be implemented, individually and/or collectively, by various types of electro-mechanical systems having a wide range of electrical components such as hardware, software, firmware, and/or virtually any combination thereof; and a wide range of components that may impart mechanical force or motion such as rigid bodies, spring or torsional bodies, hydraulics, electro-magnetically actuated devices, and/or virtually any combination thereof. Consequently, as used herein “electro-mechanical system” includes, but is not limited to, electrical circuitry operably coupled with a transducer (e.g., an actuator, a motor, a piezoelectric crystal, a Micro Electro Mechanical System (MEMS), etc.), electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of memory (e.g., random access, flash, read only, etc.)), electrical circuitry forming a communications device (e.g., a modem, module, communications switch, optical-electrical equipment, etc.), and/or any non-electrical analog thereto, such as optical or other analogs. Those skilled in the art will also appreciate that examples of electro-mechanical systems include but are not limited to a variety of consumer electronics systems, medical devices, as well as other systems such as motorized transport systems, factory automation systems, security systems, and/or communication/computing systems. Those skilled in the art will recognize that electro-mechanical as used herein is not necessarily limited to a system that has both electrical and mechanical actuation except as context may dictate otherwise.

In a general sense, those skilled in the art will also recognize that the various aspects described herein which can be implemented, individually and/or collectively, by a wide range of hardware, software, firmware, and/or any combination thereof can be viewed as being composed of various types of “circuitry” or “electrical circuitry.” Consequently, as used herein “circuitry” and “electrical circuitry” both include, but are not limited to, electrical circuitry having at least one discrete electrical circuit, electrical circuitry having at least one integrated circuit, electrical circuitry having at least one application specific integrated circuit, electrical circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), electrical circuitry forming a memory device (e.g., forms of memory (e.g., random access, flash, read only, etc.)), and/or electrical circuitry forming a communications device (e.g., a modem, communications switch, optical-electrical equipment, etc.). Those having skill in the art will recognize that the subject matter described herein may be implemented in an analog or digital fashion or some combination thereof.

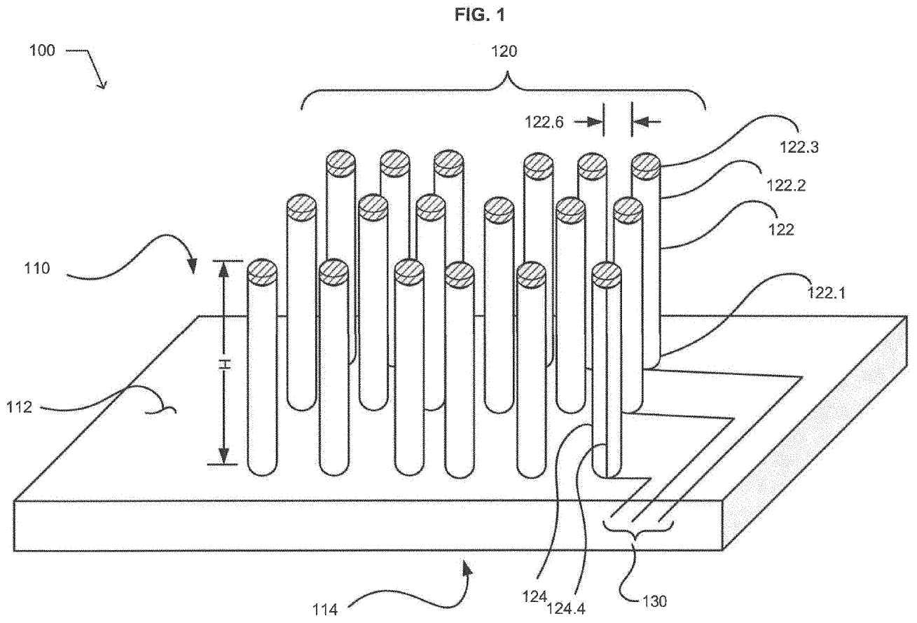

FIG. 1 illustrates an embodiment of an apparatus 100. The apparatus includes a base 110 having a first surface 112. The apparatus includes an array of pillars 120. Each pillar of the array of pillars includes a first end attached to the first surface of the base, a second end having an electric charge retention portion, a physical separation from adjacent pillars of the array of pillars, and an electrical conductor configured to electrically connect the electric charge retention portion with a bus structure. FIG. 1 illustrates features of the pillars by reference to pillar 122 and pillar 124. Pillar 122 illustrates a first end 122.1 attached to the first surface of the base, a second end 122.2 having an electric charge retention portion 122.3, and a physical separation 122.6 from adjacent pillars of the array of pillars. Pillar 124 illustrates an electrical conductor 124.4 or semiconductor configured to electrically connect the electric charge retention portion 122.3 with a bus structure 130. The apparatus 100 includes the bus structure 130 is configured to addressably connect with the electrical conductor 124.4 of each respective pillar 120 of the array of pillars 120. In an embodiment, the bus structure 124.4 is electrically isolated from the base 110. In an embodiment, the bus structure 124.4 is electrically isolated from the base 110 and configured to addressably connect with the electrical conductor 124.4 of each respective pillar 120 of the array of pillars 120.

In an embodiment, the array of dielectric pillars 120 acts like a 1-D or 2-D piezo-electric surface, where lateral SAW-like waves can propagate along the array, generating (and being acted upon) EM waves at the caps. In an embodiment, the array of dielectric pillars 120 allow a design-in different propagation speeds and dispersions in different directions by choosing the orientation and stiffness of the pillars. The symmetry class of the 2-D array can be controlled by placement of the pillars 120 (e.g., via pre-formation lithography or sphere placement prior to nano-sphere lithography, or by simply pruning unwanted pillars). In an embodiment, the pillars 120 may be built with desired orientations and beam profiles, so that some are stiffer in one direction, and others in another direction.

In an embodiment, the pillars 120 of the array of pillars 120 all have essentially the same height, so the charged caps 122.3 lie in a plane, and interact with each other in this plane. In an embodiment, some pillars 120 may be designed to have slightly different heights than others, allowing exploitation of slight out-of-plane forces for extra design freedom. The caps 122.3 are not mechanically linked together within the plane, but are electromechanically coupled. The caps 122.3 are coupled through the motion of their respective pillars 120; each of which acts like a cantilever beam, with both mechanical and inertial stiffness.

In an embodiment of the apparatus 100, the base 110 includes the bus structure 130. In an embodiment, the base 110 includes a planar base. In an embodiment, the base 110 includes a flexible base. For example, a flexible base includes a base 110 repeatedly able to bend and not crack or lose its other properties, not stretch. In an embodiment, the base 110 includes a flexible material wearable by or integratable into a fabric wearable by a human user. In an embodiment, the base 110 includes a rigid base. In an embodiment, the base 110 includes an electronic substrate material. In an embodiment, the base 110 includes a material structured to propagate surface acoustic waves. In an embodiment, the material is structured to propagate surface acoustic waves in the kilohertz to gigahertz range. In an embodiment, the base 110 includes a material structured to propagate bulk acoustic waves. In an embodiment, the material is structured to propagate bulk acoustic waves in the kilohertz to gigahertz range. In an embodiment, the base 110 includes a second 114 surface opposite the first surface 112 and configured to reflect electromagnetic waves.

In an embodiment of the apparatus 100, the array of pillars 120 includes a patterned array of pillars 120. For example, a patterned array of pillars 120 may include an arrangement or density of pillars 120 that will effect a parameter of the base 110. In an embodiment, the array of pillars 120 includes the first ends 122.1 of the pillars 120 arranged on the first surface 112 of the base 110 in a two-dimensional pattern. For example, the two-dimensional pattern may include a rectangular pattern, or a hexagonal pattern. For example, the axes defining the two-dimensional pattern directions may be orthogonal or inclined. In an embodiment, the array of pillars 120 includes an arbitrarily arranged array of pillars 120. In an embodiment, the array of pillars 120 includes an array of flexible pillars. In an embodiment, the array of pillars 120 is configured so that the second ends 122.3 can move or flex relative to the base 110. In an embodiment, the array of pillars 120 includes an array of pillars 120 each having a selected elasticity. In an embodiment, the array of pillars 120 includes an array of elongated pillars. In an embodiment, the array of pillars 120 includes an array of high-aspect-ratio pillars. For example, high-aspect ratio pillars may have an aspect ratio between 3:1 and 30:1. For example, high-aspect ratio pillars may have an aspect ratio between 30:1 and 1000:1. For example, non-high-aspect ratio pillars may have an aspect ratio between 1:1 and 3:1.

In an embodiment, at least two pillars 120 of the array of pillars 120 have a pillar height H above the base, between 0.1 and 1.0 mm. For example, pillar heights of between 0.1 and 1.0 mm may be used in a wearable device. In an embodiment, at least two pillars 120 of the array of pillars 120 have a pillar height H between 1 micron and 100 microns. For example, pillar heights of between 1 micron and 100 micron may be used in electronic sensors or acoustic wave filters. In an embodiment, at least two pillars 120 of the array of pillars 120 have a pillar height H between 1 mm to 3 cm. For example, pillar heights of between 1 mm to 3 cm may be used in some structural applications.

In an embodiment, a spacing 122.6 between the pillars of the array of pillars 120 is a constant distance. In an embodiment, a spacing between the pillars 120 of the array of pillars 120 spatially varies. In an embodiment, at least one pillar 120 of the array of pillars 120 has a first moment of inertia in a first direction and a second moment of inertia in a second direction. In an embodiment, at least one pillar 120 of the array of pillars 120 has a circular cross-section. In an embodiment, at least one pillar 120 of the array of pillars 120 has a square or rectangular cross-section. In an embodiment, at t least one pillar 120 of the array of pillars 120 has a hollow cross-section. In an embodiment, at least one pillar 120 of the array of pillars 120 has an I-beam cross-section. In an embodiment, at least one pillar 120 of the array of pillars 120 includes a cross-section that varies along its length. In an embodiment, at least one pillar 120 of the array of pillars 120 includes a cross-section that is larger at the first end 122.1 than a cross-section at a second end 122.2. In an embodiment, at least one pillar 120 of the array of pillars 120 includes a cross-section that is larger than a cross-section of the first end 122.1 and larger than a cross-section of the second end 122.2. In an embodiment, at least one pillar 120 of the array of pillars 120 has a lateral aspect ratio greater than 1:1. For example, a lateral aspect ratio may be up to 2:1. For example, a lateral aspect ratio may be up to 3:1. For example, a lateral aspect ratio may be up to 10:1. For example, a lateral aspect ratio may be greater than 10:1. For example, high lateral aspect ratios may be used to effectively deliver one-dimensional vibrations. In an embodiment, at least one pillar 120 of the array of pillars 120 has a lateral aspect ratio greater than 10:1

In an embodiment, a pillar 120 of the array of pillars 120 includes a microcolumn pillar or a microcone pillar. In an embodiment, the array of pillars 120 includes at least two parallelepiped pillars. In an embodiment, the at least two parallelepiped pillars have their respective second ends 122.2 orientated in a common direction, permitting only a one-dimensional movement by the respective second ends 122.2 of the at least two pillars 120. In an embodiment, the array of pillars 120 includes at least two rectangular cuboid pillars. In an embodiment, the at least two rectangular cuboid pillars have their respective second ends 122.2 orientated in a common direction, permitting only a one-dimensional movement by the respective second ends 122.2 of the at least two pillars 120. In an embodiment, the array of pillars 120 includes at least two columnar pillars.

In an embodiment, the at least two columnar pillars have their respective second ends 122.2 orientated in two common directions, permitting two-dimensional movement of the second ends 122.2 of the at least two pillars 120. In an embodiment, the array of pillars 120 includes a first pillar having a first length or height and a second pillar having a second length or height greater than the first length. In an embodiment, the array of pillars 120 includes at least two pillars 120 formed using a nanosphere lithography. In an embodiment, the array of pillars 120 includes an array of dielectric pillars. In an embodiment, each pillar 120 of the array of pillars 120 includes an electrical insulator portion, illustrated by the physical separation 122.6, separating the electric charge retention portion 122.3 from the first end 122.1 of the pillar 120. In an embodiment, the array of pillars 120 includes at least two dielectric pillars each having a relative permittivity greater than 3. In an embodiment, the array of pillars 120 includes at least two dielectric pillars each having a relative permittivity greater than 11. For example, silicon has a relative permittivity of 11.7. In an embodiment, the first end 122.1 of each respective pillar of the array of pillars 120 is rigidly attached to the first surface 112 of the base 110. In an embodiment, the first end 122.1 of each respective pillar of the array of pillars 120 is attached to the first surface 112 of the base 110 with a longest axis of each pillar 120 having a perpendicular orientation to the first surface 112. In an embodiment, each pillar 120 of the array of pillars 120 further includes a flexible mid-portion located between the first end 122.1 and the second end 122.2 of the pillar. In an embodiment, each pillar of the array of pillars 120 further includes a rigid mid-portion located between the first end 122.1 and the second end 122.2 of the pillar 120.

In an embodiment of the apparatus 100, the electric charge retention portion 122.3 of at least one pillar 120 of the array of pillars 120 includes two separate electric charge retention portions 122.3 carried on respective opposing sides of the pillar 120. In an embodiment, the electric charge retention portion 122.3 of at least one pillar 120 of the array of pillars 120 includes an electrically conductive cap. For example, an advantage of the array of pillars is that they provide a natural way to add or subtract charge from the caps (i.e., by giving them some conductivity). Charges can be selectively applied to individual pillar-caps, giving a way to control the effective symmetry of the 2-D construct, as well as dynamic control. A global charge applied to the caps at the tops of the pillars 120 will induce a balancing charge at the base 110; the whole thing acting like a capacitor with the pillars as the intervening dielectric. However, because the tips are unconnected to each other, their electric repulsion causes the surface to curve. This is nominally a uniform curvature, but can be modified by how the pillars 120 are placed and oriented.

In an embodiment of the apparatus 100, the physical separation includes an electrical separation from adjacent pillars of the array of pillars 120. The physical separation is illustrated by the physical separation 122.6. In an embodiment, the physical separation 122.6 includes an air or dielectric-filed gap separation from adjacent pillars of the array of pillars 120. In an embodiment, the electric charge retention portion, illustrated by the electric charge retention portion 122.3 of at least one pillar of the array of pillars 120 includes a permanently magnetic portion.

In an embodiment of the apparatus 100, the electrical conductor, illustrated by electrical conductor 124.4, is carried by an outer surface of at least one pillar 120 of the array of pillars 120. In an embodiment, the electrical conductor 124.4 is covered by an insulating material along an outer surface of at least one pillar 120 of the array of pillars 120. In an embodiment, the electrical conductor 124.4 is carried inside at least one pillar 120 of the array of pillars 120. In an embodiment, the electrical conductor 124.4 of at least one pillar 120 of the array of pillars 120 is electrically connected to bus structure 130 by an electric switching circuit. For example, the electric switching circuit may be located on a pillar 120, such as proximate to the first end 122.1 or the second end 122.2, or somewhere in between. For example, the electric switching circuit may be located within the bus structure 130 (i.e., electrically upstream of the pillar's conductor 124.4).

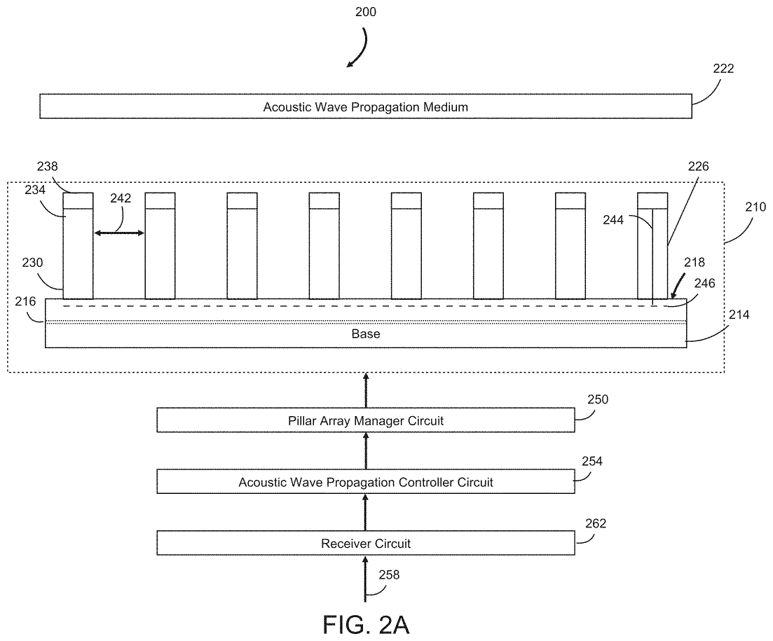

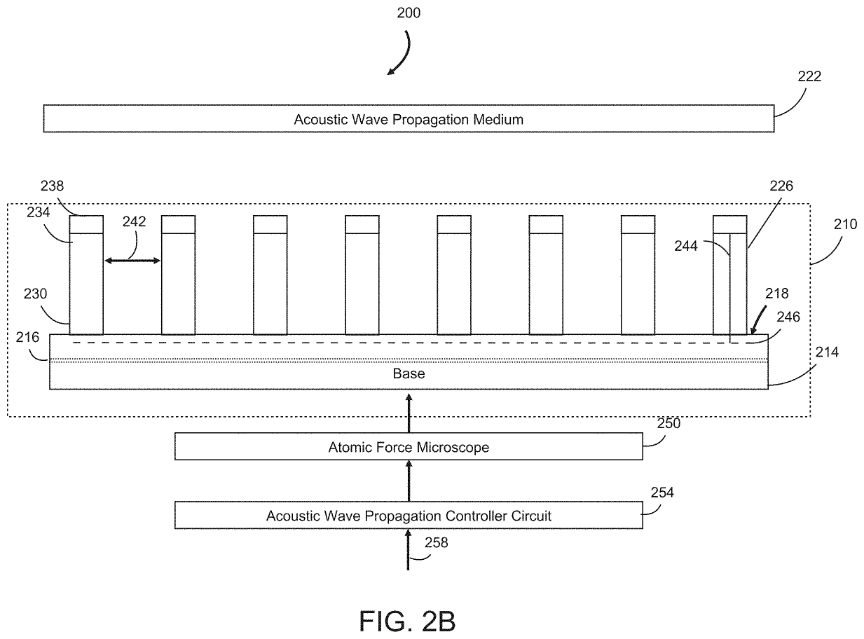

In an embodiment, the base 110 includes an electrically conductive plane (e.g., as described with reference to FIG. 2A). In an embodiment, the electrically conductive plane includes a first electrically conductive plane located electromagnetically proximate to a first group of pillars 120 of the array of pillars 120 and a second electrically conductive plane located electromagnetically proximate to a second group of pillars 120 of the array of pillars 120. In an embodiment, the first surface 112 of the base 110 includes the electrically conductive plane.

FIG. 2A illustrates an example system 200. The system includes an apparatus 210. The apparatus 210 includes a base 214 coupleable with an acoustic wave propagation medium 222 and having a first surface 218. In an embodiment, the base 214 couplable with an acoustic wave propagation medium 222 includes a base 214 configured to be or structurally capable of being coupled with an acoustic wave propagation medium 222. The apparatus 210 includes an array of pillars 226. Each pillar 226 of the array of pillars 226 includes a first end 230 attached to the first surface 218 of the base, a second end 234 having an electric charge retention portion 238, a physical separation 242 from adjacent pillars of the array of pillars, and an electrical conductor 244 configured to electrically connect the electric charge retention portion 238 with a bus structure 246. The apparatus 210 includes the bus structure 246 configured to addressably connect the electrical conductor of each respective pillar 226 of the array of pillars 226 with a pillar array manager circuit 250.

The system 200 includes the pillar array manager circuit 250 configured to apply a voltage to the respective electric charge retention portion 238 of each pillar 226 of the array of pillars 226. In an embodiment, the pillar array manager circuit 250 is configured to apply a voltage to the respective electric charge retention 238 portion of each pillar 226 of the array of pillars 226. The system 200 includes an acoustic wave propagation controller circuit 254. The acoustic wave propagation controller circuit 254 is configured to receive an electrical signal 258. In an embodiment, the electrical signal 258 may have a time varying waveform, for example, such as in a cellular communication system or satellite communication system. In an embodiment, the electrical signal 258 may have a frequency varying waveform. The acoustic wave propagation controller circuit 254 is configured to select a voltage of the electric charge retention portion 238 of each respective pillar 226 of the array of pillars 226. The voltages are selected to create in the acoustic wave propagating medium 222 an acoustic wave representative of the received electrical signal 258. For example, in an embodiment, the voltages are selected to create an acoustic wave in the acoustic wave propagation medium 222 representative of a received streaming electrical signal 258. For example, in an embodiment, the voltages are selected to convert a received streaming or continuous electric signal 258 into a streaming or continuous acoustic wave traveling in the acoustic wave propagation medium 222. The acoustic wave propagation controller circuit 254 is configured to instruct the pillar array manager circuit 250 to apply the selected voltage to the electric charge retention portion 238 of each respective pillar 226 of the array of pillars 226.

In an embodiment of the apparatus 210, the base 214 further includes the bus structure 246. In an embodiment, the base 214 is mechanically or physically coupleable with an acoustic wave-propagation medium 222. In an embodiment, the acoustic wave-propagation medium 222 includes a surface acoustic wave-propagation medium. For example, the surface acoustic wave-propagation medium may include a piezoelectric material. In an embodiment, the acoustic wave-propagation medium 222 includes a bulk acoustic wave-propagation medium. In an embodiment, the base 214 is coupled with the acoustic wave propagation medium 222. In an embodiment, the pillar array manager circuit 250 is configured to apply the selected voltage to the electric charge retention portion 238 of each respective pillar 226 of the array of pillars 226 using the bus structure 246. In an embodiment, selecting the voltage includes selecting a first voltage of the electric charge retention portion 238 of a first pillar 226 of the array of pillars 226 and selecting a second voltage of the electric charge retention portion 238 of a second pillar 226 of the array of pillars 226, the first and second selected voltages having a same polarity. In an embodiment, the select a voltage includes select a first voltage of the electric charge retention portion 238 of a first pillar 226 of the array of pillars 226 and select a second voltage of the electric charge retention portion 238 of a second pillar 226 of the array of pillars 226, the first and second selected voltages having an opposite polarity. In an embodiment, the base 214 includes an electrically conductive plane 216. In an embodiment, the pillar array manager circuit 250 is configured to apply the selected voltage to the electric charge retention portion 238 of each respective pillar 226 of the array of pillars 226 using the bus structure 246 and the electrically conductive plane 216. In an embodiment, the system 200 includes a receiver circuit 262 configured to receive the electrical signal 258.

FIG. 2B illustrates an embodiment of the system 200 operating with an atomic force microscope. The system includes an apparatus 210. The apparatus 210 includes a base 214 coupleable with an acoustic wave propagating medium 222 and having a first surface 218. The apparatus 210 includes an array of pillars 226. Each pillar 226 of the array of pillars 226 includes a first end 230 attached to the first surface 218 of the base 214, a second end 234 having an electric charge retention portion 238, and a physical separation 242 from adjacent pillars 226 of the array of pillars 226. The apparatus 210 includes an acoustic wave propagation controller circuit 254. The acoustic wave propagation controller circuit 254 is configured to receive an electrical signal 258. The acoustic wave propagation controller circuit 254 is configured to select a voltage of the electric charge retention portion 238 of each respective pillar 226 of the array of pillars 226, the voltages selected to create an acoustic wave in the acoustic wave propagating medium 222 representative of the received electrical signal 258. The acoustic wave propagation controller circuit 254 is configured to instruct an atomic force microscope 250 to apply the selected voltage to the electric charge retention portion 238 of each respective pillar 226 of the array of pillars 226. In an embodiment, the system 200 includes the atomic force microscope 250.

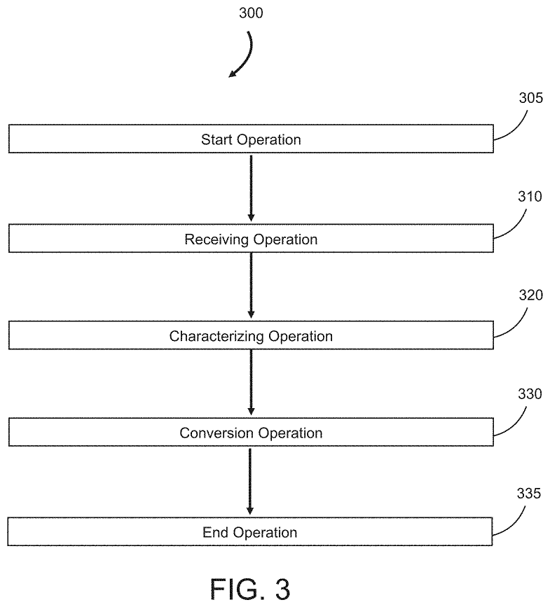

FIG. 3 illustrates an operational flow 300. The operational flow includes a start operation 305. After the start operation 305, the operational flow includes a receiving operation 310. The receiving operation 310 includes receiving an electrical signal. A characterizing operation 320 includes selecting voltages of an electric charge retention portion of each respective pillar of an array of pillars to create an acoustic wave in an acoustic wave propagation medium representative of the received electrical signal, the array of pillars each having a respective a first end attached to a first surface of a base coupled with an acoustic wave propagation medium and a second end having the electric charge retention portion. A conversion operation 330 includes applying the selected voltage to the electric charge retention portion of respective each pillar of the array of pillars. The operational flow 300 includes an end operation 335. In an embodiment, the operational flow may be implemented using the system 200 described in FIGS. 2A-2B.

In an embodiment, the conversion operation 330 includes applying the selected voltage to the electric charge retention portion of each respective pillar of the array of pillars using a bus structure configured to addressably connect with an electrical conductor of each respective pillar of the array of pillars. In an embodiment, the conversion operation 330 includes applying the selected voltage to the electric charge retention portion of each respective pillar of the array of pillars using bus structure configured to addressably connect with an electrical conductor of each respective pillar of the array of pillars and an electrically conductive plane associated with the base.

In an embodiment, the characterizing operation 320 includes selecting based on a library of at least two shape or stiffness configurations the voltages of an electric charge retention portion of each respective pillar of the array of pillars to create an acoustic wave in the acoustic wave propagation medium representative of the received electrical signal. In an embodiment, the characterizing operation 320 includes selecting by computation on the fly the voltages of an electric charge retention portion of each respective pillar of the array of pillars to create an acoustic wave in the acoustic wave propagation medium representative of the received electrical signal.

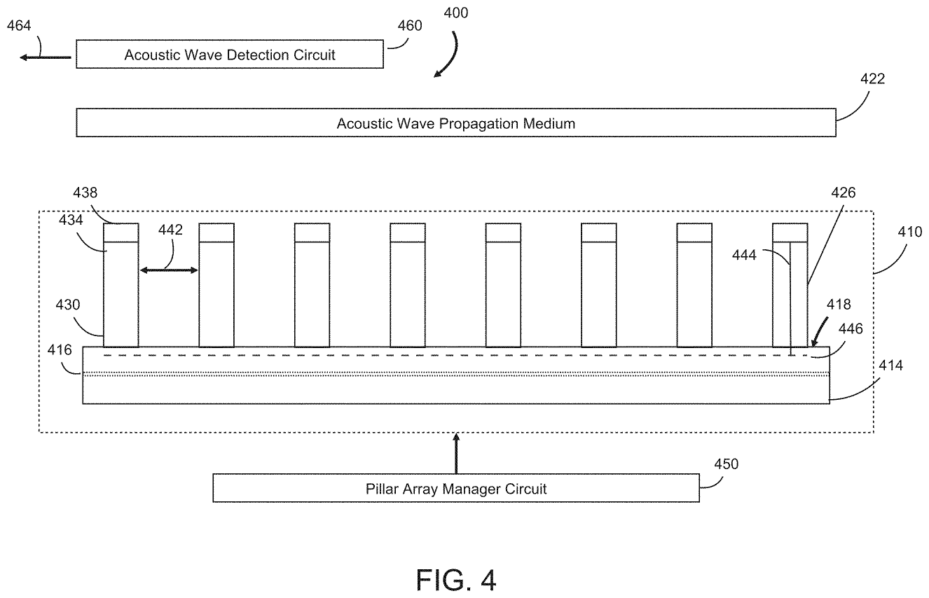

FIG. 4 illustrates an example system 400. The system includes an apparatus 410. The apparatus 410 includes a base 414 coupleable with an acoustic wave propagation medium 422 and having a first surface 418. The apparatus 410 includes an array of pillars 426. Each pillar 426 of the array of pillars 426 includes a first end 430 attached to the first surface 418 of the base 414, a second end 434 having an electric charge retention portion 438, a physical separation 442 from adjacent pillars 426 of the array of pillars 426, and an electrical conductor 444 configured to electrically connect the electric charge retention portion 438 with a bus structure 446. The system 400 includes the bus structure 446 configured to addressably connect the electrical conductor 444 of each respective pillar 426 of the array of pillars 426 with a pillar array manager circuit 450. The system 400 includes the pillar array manager circuit 450 configured to sense voltages of the electric charge retention portion 438 of each respective pillar 426 of the array of pillars 426. In an embodiment, the pillar array manager circuit 450 is configured to sense voltage differences between the electric charge retention portion 438 of a first respective pillar 426 of the array of pillars 426 and the electric charge retention portion 438 of a second respective pillar 426 of the array of pillars 426. In an embodiment, the changes in the voltage of the electric charge retention portion 438 are responsive to a wave traveling in the acoustic wave propagation medium 422. The system 400 includes an acoustic wave detection circuit 460. The acoustic wave detection circuit 460 is configured to generate an electrical signal 464 responsive to the sensed voltage changes in the electric charge retention portions 438. The acoustic wave detection circuit 460 is configured to output the generated electrical signal 464. For example, a bulk-wave or a surface acoustic wave acting on the base 414 and the pillars 426 will cause the pillars 426 to wiggle, and thus displace the charged caps 438, generating electromagnetic signals that are sensed. For example, a bulk-wave or a surface acoustic wave acting on the base 414 and the pillars 426 will cause the pillars 426 to wiggle, and thus displace the charged caps 438, generating varying voltages in the electric charge retention portions 438.

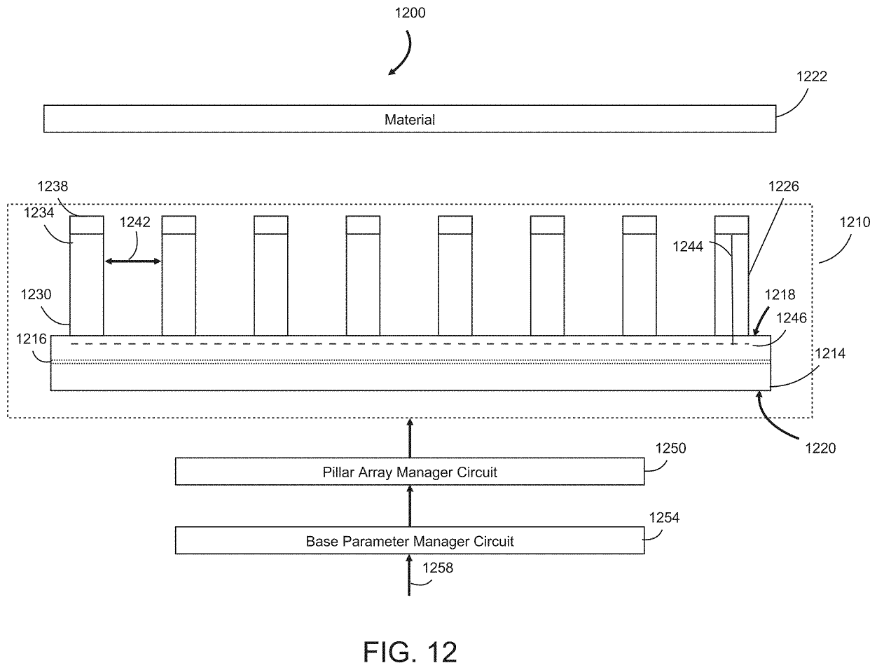

In an embodiment, the base 414 includes the bus structure. 446 In an embodiment, the base 414 includes a base 414 coupled with the wave propagation medium 422. In an embodiment, the pillar array manager circuit 450 is configured to sense the voltage of the electric charge retention portion 438 of each respective pillar 426 of the array of pillars 426 using the bus structure 446. In an embodiment, the base 414 includes an electrically conductive plane 416. In an embodiment, the pillar array manager circuit 450 is configured to sense the voltage of the electric charge retention portion 438 of each respective pillar 426 of the array of pillars 426 using the bus structure 446 and the electrically conductive plane 416. In an embodiment, the base 414 is mechanically or physically coupleable with an acoustic wave-propagation medium 422. In an embodiment, the acoustic wave-propagation medium 422 includes a surface acoustic wave-propagation medium. In an embodiment, the acoustic wave-propagation medium 422 includes a bulk acoustic wave-propagation medium. In an embodiment, the acoustic wave detection circuit 460 is further configured to detect a presence or absence of a preselected component in the generated electrical signal 464. For example, the presence or absence of the preselected component may include insufficient filtering of a frequency or frequency band. For example, the presence or absence of the preselected component may include too much filtering of a frequency or frequency band. For example, the presence or absence of the preselected component may include a shape or curvature of the base not matching requested shape. The acoustic wave detection circuit 460 is further configured to generate a variance signal responsive to the detected presence or absence of the preselected component. In an embodiment, the acoustic wave detection circuit 460 is further configured to output the variance signal. In an embodiment, the acoustic wave detection circuit 460 is further configured to detect a presence or absence of a preselected component in the generated electrical signal 464. In an embodiment, the acoustic wave detection circuit 460 is further configured to determine a correction parameter responsive to the detected presence or absence of the preselected component. In an embodiment, the acoustic wave detection circuit 460 is further configured to output a signal indicative of the determined correction parameter. In an embodiment, the determined correction parameter includes a determined correction factor in a format usable by a particular system. For example, the particular system may include the system 200 described in FIGS. 2A-2B. For example, the particular system may include the system 1200 described in FIG. 12.

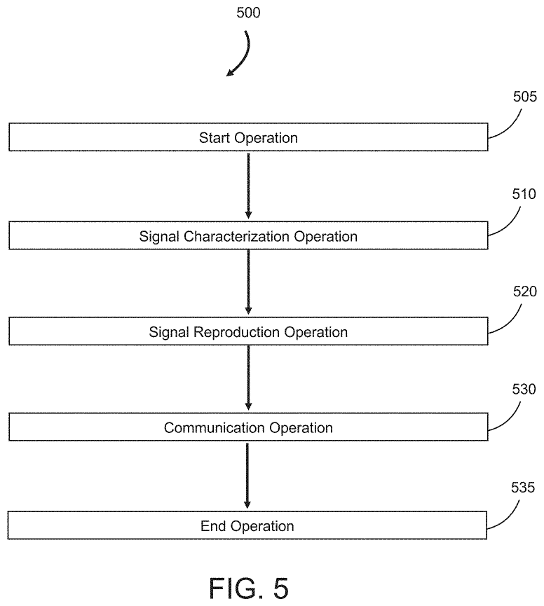

FIG. 5 illustrates an example operational flow 500. After a start operation 505, the operational flow includes a signal characterization operation 510. The signal characterization operation includes sensing voltages in an electric charge retention portion of each respective pillar of an array of pillars. The array of pillars each having a respective a first end attached to a base coupled with an acoustic wave propagation medium and a second end having the electric charge retention portion. A signal reproduction operation 520 generating an electrical signal responsive to the sensed voltages. A communication operation 530 includes outputting the generated electrical signal. The operational flow includes an end operation 535. In an embodiment, the operational flow 500 may be implemented using the system 400 described in FIG. 4.

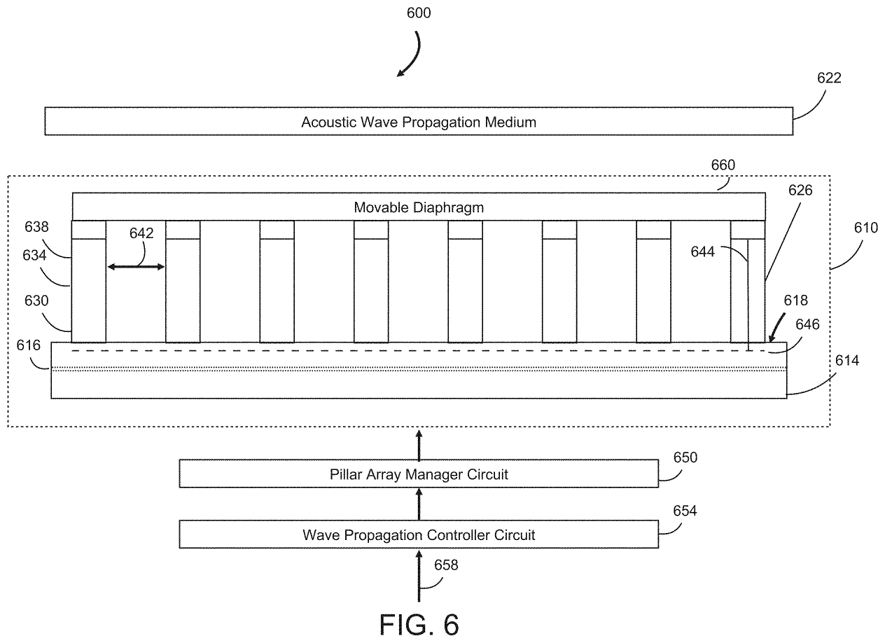

FIG. 6 illustrates an example system 600. The system includes an apparatus 610. The apparatus 610 includes a base 614 having a first surface 618. The apparatus includes an array of pillars 626. Each pillar 626 of the array of pillars 626 includes a first end 630 attached to the first surface 618 of the base 614, a second end 634 having an electric charge retention portion 638, a physical separation 642 from adjacent pillars 626 of the array of pillars 626, and an electrical conductor 644 configured to electrically connect the electric charge retention portion 638 with a bus structure 646. The system 600 includes the bus structure 646 configured to addressably connect the electrical conductor 638 of each respective pillar 626 of the array of pillars 626 with a pillar array manager circuit 650. The system 600 includes the pillar array manager circuit 650 configured to apply a voltage to the electric charge retention portion 638 of each respective pillar 626 of the array of pillars 626. The system includes a wave propagation controller circuit 654. The wave propagation controller circuit 654 is configured to receive an electrical signal 658. The wave propagation controller circuit 654 is configured to select a voltage of the electric charge retention portion 638 of each respective pillar 626 of the array of pillars 626, the voltages selected to create movements by the second end of each respective pillar 626 of the array of pillars 626 representative of the received electrical signal 658. The wave propagation controller circuit 654 is configured to instruct the pillar array manager circuit 650 to apply the respective selected voltage to the electric charge retention portion 638 of each respective pillar 626 of the array of pillars 626. The system 600 includes a movable diaphragm 660 disposed between the second end 634 of each respective pillar 626 of the array of pillars 626 and ambient air. The diaphragm 660 is configured to move in response to a movement of the second end 634 of at least one pillar 626 of the array of pillars 626.

In an embodiment of the apparatus 610, the base 614 includes the bus structure 646. In an embodiment, the pillar array manager circuit 650 is configured to apply the selected voltage to the electric charge retention portion 638 of each respective pillar 626 of the array of pillars 626 using the bus structure 646. In an embodiment, the base 614 includes an electrically conductive plane 616. In an embodiment, the pillar array manager circuit 650 is configured to apply the selected voltage to the electric charge retention portion 638 of each respective pillar 626 of the array of pillars 626 using the bus structure 646 and the electrically conductive plane 616. In an embodiment, the base 614 includes a rigid base structure. In an embodiment, the movable diaphragm 660 is configured to move independently of the base 614.

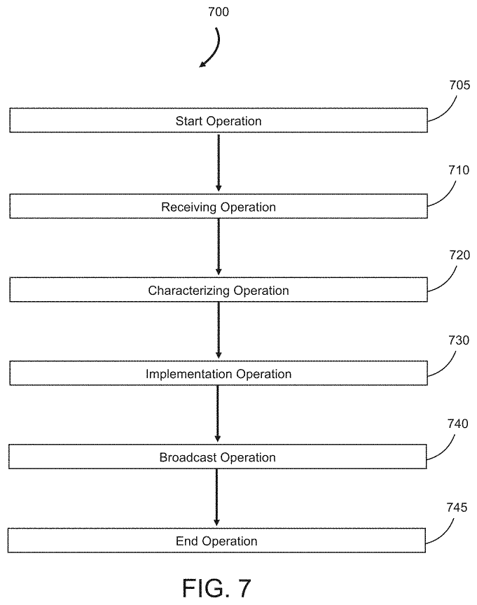

FIG. 7 illustrates an example operational flow 700. After a start operation 705, the operational flow includes a receiving operation 710. The receiving operation includes receiving an electrical signal. A characterizing operation 720 includes selecting voltages to be applied to an electric charge retention portion of each respective pillar of an array of pillars. The voltages are selected to create a movement against a movable diaphragm by the electric charge retention portion of each respective pillar of an array of pillars representative of the received electrical signal. The array of pillars each having a first end attached to a first surface of a base and a second end having the electric charge retention portion. An implementation operation 730 includes applying the selected voltages to the electric charge retention portion of respective each pillar of the array of pillars. A broadcast operation 740 includes broadcasting from the diaphragm a signal representative of the received electrical signal. The operational flow includes an end operation 745. In an embodiment, the operational flow 700 may be implemented using the system 600 described in FIG. 6.

In an embodiment of the implementation operation 730, the applying includes applying the selected voltages to the electric charge retention portion of each respective pillar of the array of pillars using a bus structure configured to addressably connect with an electrical conductor of each respective pillar of the array of pillars. In an embodiment of the implementation operation 730, the applying includes applying the selected voltages to the electric charge retention portion of each respective pillar of the array of pillars using bus structure configured to addressably connect with an electrical conductor of each respective pillar of the array of pillars and an electrically conductive plane associated with the base. In an embodiment of the implementation operation 730, the selecting includes selecting based on a library of at least two shape or stiffness configurations the voltages to be applied to electric charge retention portion of each respective pillar of an array of pillar. In an embodiment of the implementation operation 730, the selecting includes selecting by computation on the fly the voltages to be applied to electric charge retention portion of each respective pillar of an array of pillar. In an embodiment of the broadcast operation 740, the broadcasting includes broadcasting from the diaphragm an audio signal representative of the received electrical signal.

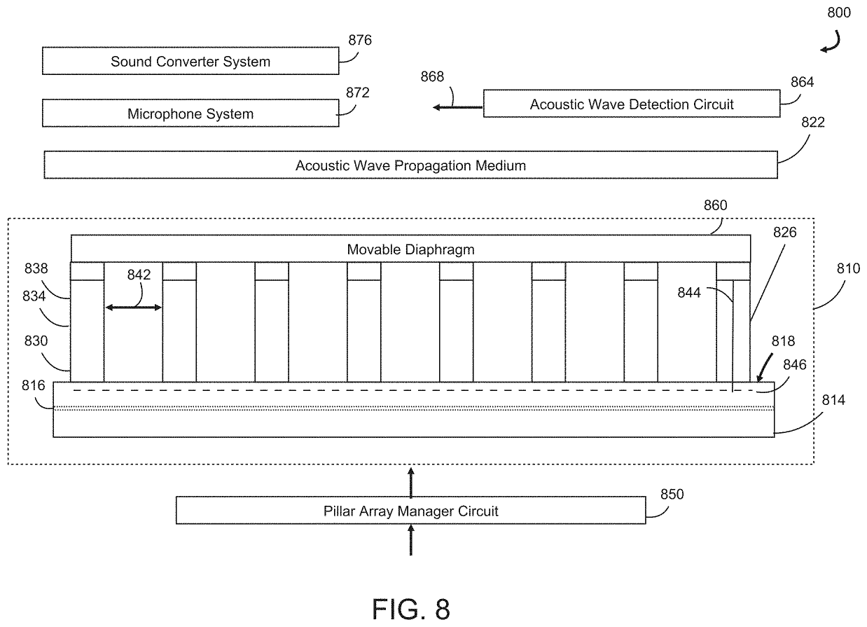

FIG. 8 illustrates an example system 800. The system 800 includes an apparatus. 810 The apparatus 810 includes a base 814 having a first surface 818. The apparatus 810 includes an array of pillars 826. Each pillar 826 of the array of pillars 826 includes a first end 830 attached to the first surface 818 of the base 814, a second end 834 having an electric charge retention portion 838, a physical separation 842 from adjacent pillars 826 of the array of pillars 826, and an electrical conductor 844 configured to electrically connect the electric charge retention portion 838 with a bus structure 846. The apparatus 810 includes the bus structure 846 configured to addressably connect the electrical conductor 844 of each respective pillar 826 of the array of pillars 826 with a pillar array manager circuit 850. The system 800 includes a movable diaphragm 860 disposed between the second end 834 of each respective pillar 826 of the array of pillars 826 and an ambient air environment. The diaphragm 860 is configured to move the electric charge retention portion 838 of each respective pillar 826 of the array of pillars 826 in response to an airborne sound wave in the ambient air environment. The system 800 includes the pillar array manager circuit 850 configured to sense voltages of the electric charge retention portion 838 of each respective pillar 826 of the array of pillars 826 created by movements the electric charge retention portion 838 of each respective pillar 826 of the array of pillars 826 in response to airborne sound waves in the ambient air environment. For example, the voltages of the electric charge retention portion 838 are responsive to an airborne sound wave incident on the movable diaphragm 860. The system 800 includes an acoustic wave detection circuit 864 configured to receive the sensed voltages of the electric charge retention portion 838 of each respective pillar 826 of the array of pillars 826. The acoustic wave detection circuit 864 is configured to generate an electrical signal 868 responsive to the sensed voltages of the electric charge retention portions 838. The acoustic wave detection circuit 864 outputs the generated electrical signal 868. For example, in an embodiment, the system 800 includes a microphone system 872 outputting a generated electrical signal 868 representative of the airborne soundwaves. For example, in an embodiment, the system 800 includes a sound converter system 876.

In an embodiment, the base 814 includes the bus structure 846. In an embodiment, the pillar array manager circuit 850 is configured to sense voltages of the electric charge retention portion 838 of each respective pillar 826 of the array of pillars 826 using the bus structure 846. In an embodiment, the base 814 includes an electrically conductive plane 816. In an embodiment, the pillar array manager circuit 850 is configured to sense voltages of the electric charge retention portion 838 of each respective pillar 826 of the array of pillars 826 using the bus structure 846 and the electrically conductive plane 816.

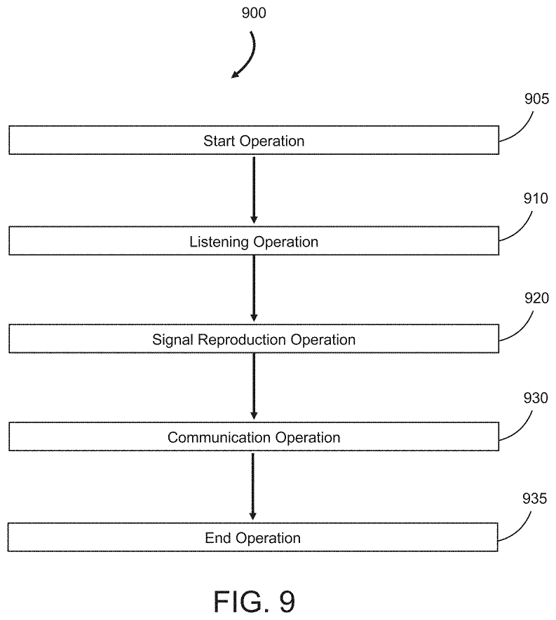

FIG. 9 illustrates an example operational flow 900. After a start operation 905, the operational flow includes a listening operation 910. The listening operation 910 includes sensing voltages of an electric charge retention portion of each respective pillar of an array of pillars produced in response to an airborne sound wave incident on a movable diaphragm. The array of pillars each having a respective a first end attached to a base and a second end having the electric charge retention portion. The movable diaphragm disposed between the second end of each respective pillar of the array of pillars and an ambient air environment. A signal reproduction operation 920 includes generating an electrical signal responsive to the sensed voltages. A communication operation 930 includes outputting the generated electrical signal. The operational flow 900 includes an end operation 935. In an embodiment, the operational flow 900 may be implemented using the system 800 described in FIG. 8.

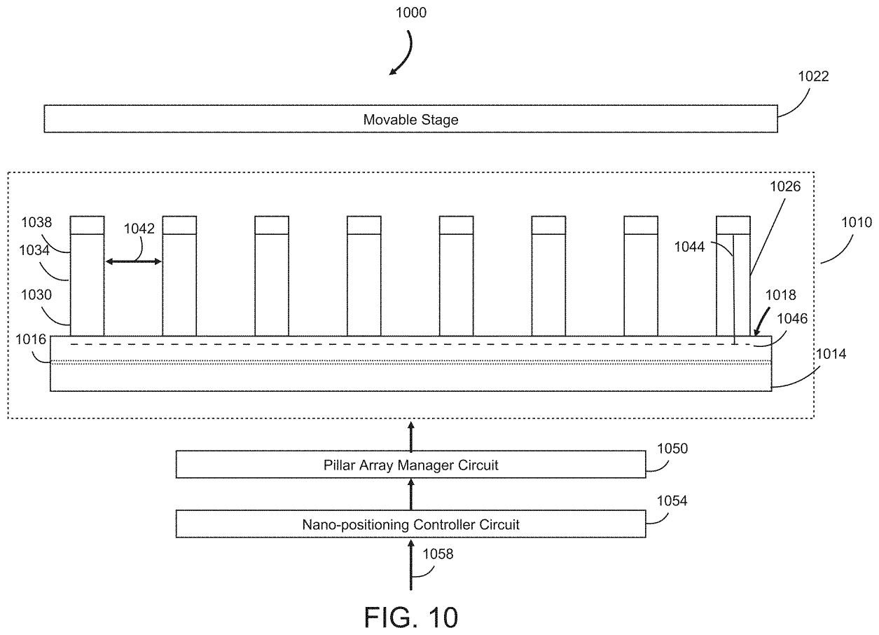

FIG. 10 illustrates an example nano-positioning device 1000. The nano-positioning device 1000 includes an actuator apparatus 1010. The actuator apparatus 1010 includes a base 1014 having a first surface 1018. The actuator apparatus 1010 includes an array of pillars 1026. Each pillar 1026 of the array of pillars 1026 includes a first end 1030 attached to the first surface 1018 of the base 1014, a second end 1034 having an electric charge retention portion 1038, a physical separation 1042 from adjacent pillars 1026 of the array of pillars 1026; and an electrical conductor 1044 configured to electrically connect the electric charge retention portion 1038 of the second end 1034 with a bus structure 1046. The actuator apparatus 1010 includes the bus structure 1046 configured to addressably connect the electrical conductor 1044 of each respective pillar 1026 of the array of pillars 1026 with a pillar array manager circuit 1050.

The nano-positioning device 1000 includes the pillar array manager circuit 1050 configured to apply a voltage to the electric charge retention portion 1030 of each respective pillar 1026 of the array of pillars 1026. The nano-positioning device 1010 includes a movable stage 1022 disposed proximate to the electric charge retention portion 1038 of at least one pillar 1026 of the array of pillars 1026. The movable stage 1022 is configured to controllably move relative to the base 1014 structure in response to a movement component of the electric charge retention portion 1038 of each respective pillar 1026 of the array of pillars 1026. In an embodiment, the movable stage 1022 is configured to controllably move relative to the base 1014 structure perpendicularly with respect to the base 1014. In an embodiment, the movable stage 1022 is configured to controllably move relative to the base 1014 structure laterally with respect to the base 1014.

The nano-positioning device 1010 includes a nano-positioning controller circuit 1054. The nano-positioning controller circuit 1054 is configured to receive an electrical signal 1058 indicative of a selected nano-positioning adjustment in the movable stage 1022. For example, the nano-positioning adjustment may be selected by a human or a machine. The nano-positioning controller circuit 1054 is configured to select a voltage of the electric charge retention portion 1038 of each respective pillar 1026 of the array of pillars 1026 implementing the selected nano-positioning adjustment. The nano-positioning controller circuit 1054 is configured to instruct the pillar array manager circuit 1058 to apply the respective selected voltage to the electric charge retention portion 1038 of each respective pillar 1026 of the array of pillars 1026.

In an embodiment, the base 1014 includes the bus structure 1046. In an embodiment, the pillar array manager circuit 1050 is configured to apply the selected voltage to the electric charge retention portion 1038 of each respective pillar 1026 of the array of pillars 1026 using the bus structure 1046. In an embodiment, the base 1014 includes an electrically conductive plane 1016. In an embodiment, the pillar array manager circuit 1050 is configured to apply the selected voltage to the electric charge retention portion 1038 of each respective pillar 1026 of the array of pillars 1026 using the bus structure 1046 and the electrically conductive plane 1016. In an embodiment, the base 1014 includes a rigid base.

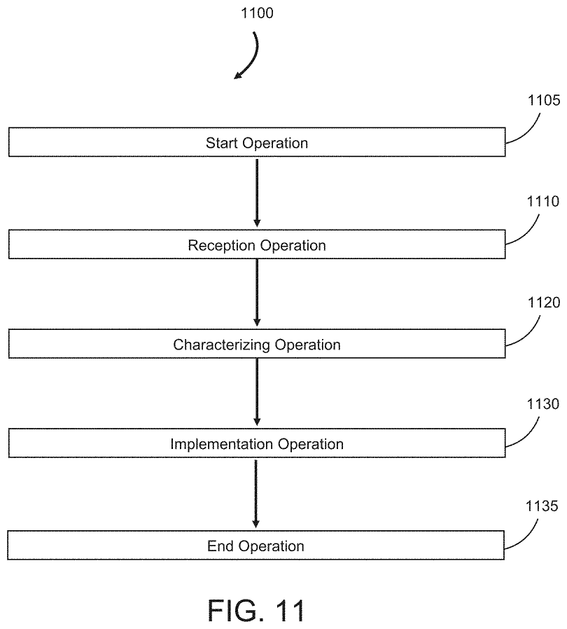

FIG. 11 illustrates an example operational flow 1100. After a start operation 1105, the operational flow 1100 includes a reception operation 1110. The reception operation includes receiving an electrical signal indicative of a selected nano-position adjustment in a movable stage. The movable stage is positioned proximate to an electric charge retention portion of each respective pillar of an array of pillars. The movable stage is configured to controllably move relative to a base structure in response to a movement component of the electric charge retention portion of at least one pillar of the array of pillars. Each pillar of the array of pillars includes a respective a first end attached to a first surface of the base and a second end having the electric charge retention portion. A characterizing operation 1120 includes selecting a voltage of the electric charge retention portion of each respective pillar of the array of pillars implementing the selected nano-positioning adjustment. An implementation operation 1130 includes applying the respective selected voltage to the electric charge retention portion of each respective pillar of the array of pillars. The operational flow 1100 includes an end operation 1135. In an embodiment, the operational flow 1100 may be implemented using the system 1000 described in FIG. 10.

FIG. 12 illustrates an example embodiment of a system 1200. The system 1200 includes an apparatus 1210. The apparatus 1210 includes a base 1214 coupleable with a material 1222 and having a first surface 1218. The apparatus 1210 includes an array of pillars 1226. Each pillar 1226 of the array of pillars 1226 includes a first end 1230 attached to the first surface 1218 of the base 1214, a second end 1234 having an electric charge retention portion 1238, a physical separation 1242 from adjacent pillars 1226 of the array of pillars 1226, and an electrical conductor 1244 configured to electrically connect the electric charge retention portion 1238 with a bus structure 1246. The apparatus 1210 includes the bus structure 1246 configured to addressably connect the electrical conductor 1244 of each respective pillar 1226 of the array of pillars 1226 with a pillar array manager circuit 1250. The system 1200 includes the pillar array manager circuit 1250 configured to apply a voltage to the electric charge retention portion 1238 of each respective pillar 1226 of the array of pillars 1226. The system 1200 includes a base parameter manager circuit 1254. The base parameter manager circuit 1254 is configured to receive a request 1258 for a selected shape or stiffness of the base 1214. For example, a selected stiffness will effect a waveform propagation parameter of the base 1214. For example, a selected shape may include a one-dimensional or two-dimensional curve of the base 1214. The base parameter manager circuit 1254 is configured to select a voltage of the electric charge retention portion 1238 of each respective pillar 1226 of the array of pillars 1226. The voltages are selected to implement the requested shape or stiffness in the base 1214. The base parameter manager circuit 1254 is configured to instruct the pillar array manager circuit 1250 to apply the selected voltage to the electric charge retention portion 1238 of each respective pillar 1226 of the array of pillars 1226. In an embodiment, the system 1200 is configured to change a shape or stiffness of the base 1214 or an electromagnetic wave reflecting surface. In an embodiment, the system 1200 is configured to change a shape of a wearable fabric, or stiffen or relax an acoustic wave propagation medium.

In an embodiment of the system 1200, the base 1214 includes the bus structure 1246. In an embodiment, the material 1222 includes a flexible material wearable by or integrated into a fabric wearable by a human user. In an embodiment, the material 1222 includes an acoustic wave propagation medium. In an embodiment, the receive includes receive a request 1258 from a human user for a selected shape or stiffness of the base 1214. In an embodiment, the receive includes receive a request 1258 from a machine for a selected shape or stiffness of the base 1214. In an embodiment, the request 1258 is received from a computing machine. In an embodiment, the receive includes receive a request 1258 for a selected shape or stiffness of the first surface 1218 of the base. In an embodiment, the receive includes receive a request 1258 for a selected shape or stiffness of a second surface 1220 of the base 1214, the second surface 1220 opposite the first surface 1218. In an embodiment, the receive includes receive a request 1258 for a shape of the base 1214. In an embodiment, the receive includes receive a request 1258 for a stiffness of the base 1214. In an embodiment, the receive includes receive a request 1258 for a flexibility of the base 1214. For example, the request for a flexibility may include a request for a resistance to bending or flexing of the base 1214. In an embodiment, the receive includes receive a request 1258 for a shape or contour of the first surface 1218 of the base 1214. In an embodiment, the receive includes receive a request 1258 for a shape, stiffness, flexibility, or contour of a second surface 1220 of the base 1214, the second surface 1220 opposite the first surface 1218. In an embodiment, the select includes select based on a library of at least two shape or stiffness configurations a voltage of the electric charge retention portion 1238 of each respective pillar 1226 of the array of pillars 1226 implementing the requested shape or stiffness. In an embodiment, the select includes select by a computation on the fly the voltage of the electric charge retention portion 1238 of each respective pillar 1226 of the array of pillars 1226 implementing the requested shape or stiffness.

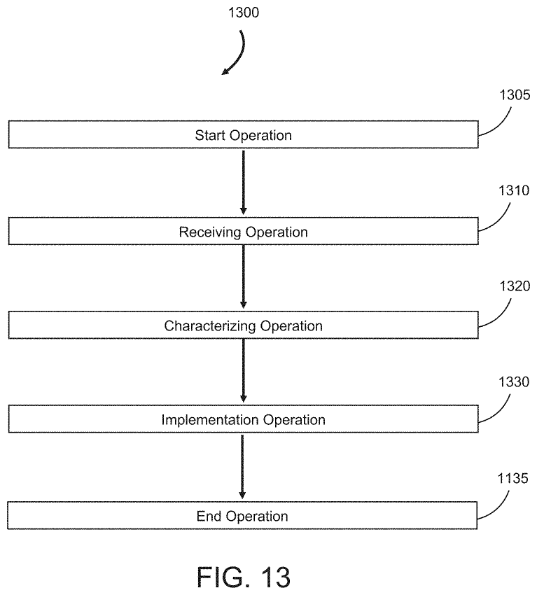

FIG. 13 illustrates an example operational flow 1300. After a start operation 1305, the operational flow includes a receiving operation 1310. The receiving operation 1310 includes receiving a request for a selected shape or stiffness of a base of an apparatus, the apparatus including the base coupleable with a material and having a first surface. A characterizing operation 1320 includes selecting voltages of an electric charge retention portion of each respective pillar of an array of pillars. The array of pillars each having a respective a first end attached to a first surface of the base and a second end having the electric charge retention portion. The voltages are selected to implement the requested shape or stiffness in the base. An implementation operation 1330 includes applying the selected voltage to the electric charge retention portion of respective each pillar of the array of pillars. The operational flow 1300 includes an end operation 1335. In an embodiment, the operational flow 1300 may be implemented using the system 1200 described in FIG. 12.

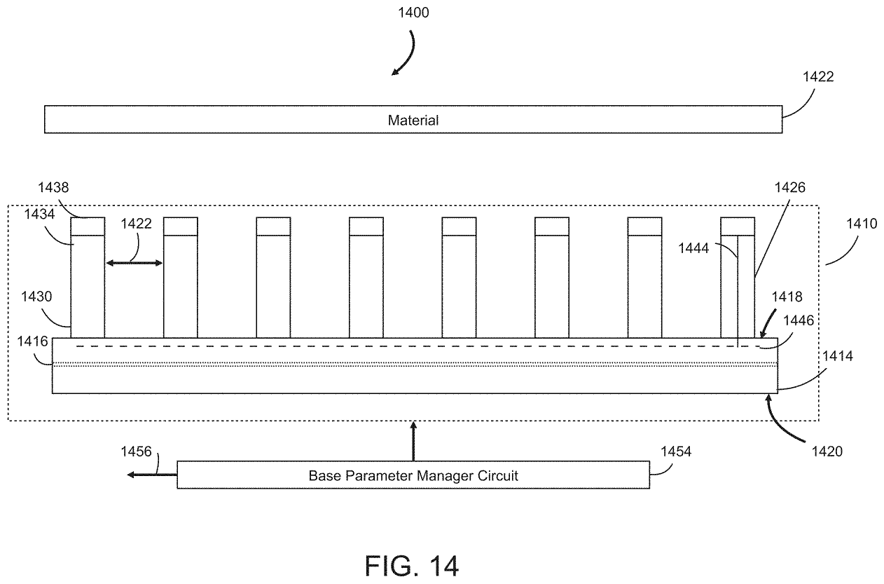

FIG. 14 illustrates an example system 1400. The system 1400 includes an apparatus 1410. The apparatus 1410 includes a base 1414 coupleable with a material 1422 and having a first surface 1418. The apparatus 1410 includes an array of pillars 1426. Each pillar 1426 of the array of pillars 1426 includes a first end 1430 attached to the first surface 1418 of the base 1414, a second end 1434 having an electric charge retention portion 1438, a physical separation 1442 from adjacent pillars 1426 of the array of pillars 1426, and an electrical conductor 1444 configured to electrically connect the electric charge retention portion 1438 with a bus structure 1446. The apparatus 1410 further includes the bus structure 1446 configured to addressably connect the electrical conductor 1446 of each respective pillar 1426 of the array of pillars 1426 with a pillar array manager circuit 1450. The system 1400 includes the pillar array manager circuit 1450 configured to sense voltages of the electric charge retention portion 1438 of each respective pillar 1426 of the array of pillars 1426. The system 1400 includes a base parameter manager circuit 1454 configured to determine a shape of the base 1414 in response the sensed voltages. The base parameter manager circuit 1454 is also configured to generate an electrical signal 1456 indicative of the determined shape of the base. The base parameter manager circuit 1454 is also configured to output the electrical signal 1456 indicative of the determined shape of the base 1414. For example, in an embodiment, the system 1400 is configured to determine a shape of the base 1414 and/or a material 1422 coupled with the base 1414. For example, in an embodiment, the system 1400 is configured to determine a shape of the base 1414 and/or a reflecting surface 1423 of a material 1422 coupled with the base 1422. For example, an application for the system 1400 as an electronic sensor for the shape of a surface, such a particular curvature or shape of a surface.

In an embodiment of the system 1400, the base 1414 is coupled with the material 1422. In an embodiment of the system 1400, the material 1422 includes a flexible material wearable by or integrated into a fabric wearable by a human user. In an embodiment, the material 1422 includes an acoustic wave-propagation medium. In an embodiment, the base 1414 includes a second surface 1420 opposite the first surface 1418 and configured to reflect electromagnetic waves. For example, in an embodiment, the second surface 1420 is an adaptively shapeable or reconfigurable electromagnetic wave reflector antenna. In an embodiment, the electromagnetic waves include radiofrequency electromagnetic waves. In an embodiment, the electromagnetic waves include light frequency electromagnetic waves. For example, in an embodiment, the second surface 1420 is an adaptively shapeable or reconfigurable mirror.

In an embodiment of the system 1400, the base parameter manager circuit 1454 is further configured to sample the voltage of the electric charge retention portion 1438 of each respective pillar 1426 of the array of pillars 1426 at a rate equal to or greater than the Nyquist rate. In an embodiment of the base parameter manager circuit 1454, the determine a shape further includes determine a shape parameter of the base 1414 in response the sensed voltages. In an embodiment, the determine a shape further includes determine a shape and a stiffness parameter of the base 1414 in response the sensed voltages. For example, a stiffness parameter may include a resistance to an acoustic wave, or a resistance to bending or flexing of the base. In an embodiment, the determine a shape further includes determine a shape and a flexibility parameter of the base 1414 in response the sensed voltages. For example, a flexibility parameter may include a resistance to bending or flexing of the base 1414. In an embodiment, the determine a shape further includes determine a shape or contour parameter of the first surface 1418 of the base 1414 in response the sensed voltages. In an embodiment, the determine a shape further includes determine a shape or contour parameter of a second surface 1420 of the base 1414 in response the output information, the second surface 1420 opposite the first surface 1418. In an embodiment, the determine a shape further includes determine a resonance parameter of the base 1414 in response the sensed voltages.

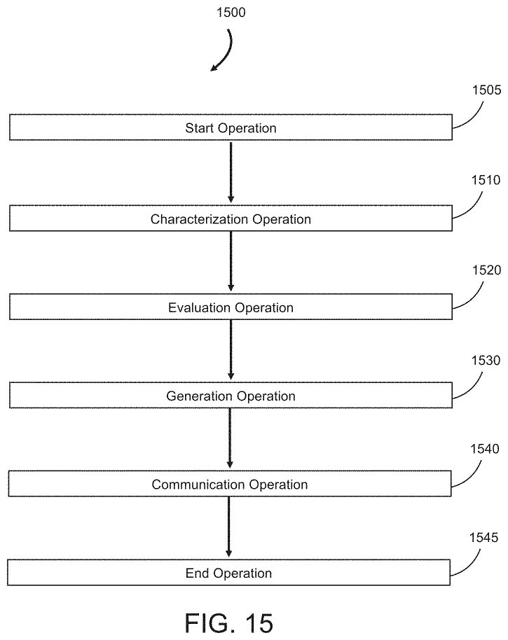

FIG. 15 illustrates an example operational flow 1500. After a start operation 1505, the operational flow includes a characterization operation 1510. The characterization operation 1510 includes sensing voltages of an electric charge retention portion of each respective pillar of an array of pillars. The array of pillars each having a respective a first end attached to a base coupled with a material and a second end having the electric charge retention portion. An evaluation operation 1520 includes determining a shape of the base in response the sensed voltages. A generation operation 1530 includes generating an electrical signal indicative of the determined shape of the base. A communication operation 1540 includes outputting the electrical signal indicative of the determined shape of the base. The operational flow 1500 includes an end operation 1545. For example, in an embodiment, the operational flow 1500 may output information indicative of a shape of the base or a reflecting surface coupled with the base. In an embodiment, the operational flow 1500 may be implemented using the system 1400 described in FIG. 15.

In an embodiment, a way to form a dynamically controllable 2-D artificial piezoelectric material, is to exploit the 3rd, perpendicular, direction. Make the material from an array (a forest) of dielectric pillars, each with a charged tip (e.g., a metal cap). For example, nanosphere lithography can be used to form such forests. In an embodiment, the pillars all have essentially the same height, so they charged caps lie in a plane, and interact with each other in this plane (alternatively, some pillars have slightly different heights than others, allowing exploitation of slight out-of-plane forces for extra design freedom). The caps are not mechanically linked together within the plane, but are indirectly mechanically coupled through motion of their respective pillars; each of which acts like a cantilever beam, with both mechanical and inertial stiffness. A bulk-wave or a SAW acting on the substrate of the pillars will cause the pillars to wiggle, and thus displace the charged caps, generating EM signals there. The forest acts like a 2-D piezo-electric surface, lateral SAW-like waves can propagate along the forest, generating (and being acted upon) EM waves at the caps. We can design-in different propagation speeds and dispersions in different directions by choosing the orientation and stiffness of the pillars; we can achieve some dynamic control by adding/removing charge from the caps in desired regions or patterns. We can control the symmetry class of the 2-D array, by placement of the pillars (e.g., via pre-formation lithography or sphere placement prior to nano-sphere lithography, or by simply pruning unwanted pillars). We can build pillars with desired orientations and beam profiles, so that some are stiffer in one direction, and others in another direction. Another advantage of the pillars is that they provide a natural way to add or subtract charge from the caps (i.e., by giving them some conductivity). Charges can be selectively applied to individual pillar-caps, giving us another way to control the effective symmetry of the 2-D construct, as well as dynamic control. A global charge applied to the caps at the tops of the pillars will induce a balancing charge at the base; the whole thing acting like a capacitor with the pillars as the intervening dielectric. Because the tips are unconnected to each other, their electric repulsion causes the surface to curve. This is nominally a uniform curvature, but can be modified by how the pillars are placed and oriented.

An application of such 2-D “material” is either as a sensor for the shape of the surface (surface curvature can be electrically sensed) or for a way to actively control the shape (voltage applied to various pillar-caps will apply forces between them, and thereby change the curvature of the surface. One use for this is in smart clothes.

In an embodiment, a piezoelectric material is made from polarized material that that undergoes internal displacements, e.g., deformation of a polarized crystal, or polarized molecules that get shifted relative to each other. We can make an artificial piezo material on the mesa-scale; form a bunch of polarized structures linked together with elastic elements so that they can be displaced, changing the polarization. Displacements can change the length of each dipole moment, or the angle or spacing between neighboring dipoles. An advantage is that each dipole is large, so can hold a lot of charge, thereby having a large dipole moment; the counter, of course, is that the density of them is lower. Another aspect is that the overall crystal symmetry has to be chosen properly; for in some symmetry classes, effects will cancel out. Fortunately, since this is an artificial material, we can arrange it with the right symmetry; types which reinforce the interactions, not cancel them. One implementation is where each polarized “molecule” consists of a dielectric rod (with desired elasticity) and charged metal balls on each end. An array of such “molecules” is laid out, in a selected symmetry pattern. The space between “molecules” is filled with a dielectric, having desired elasticity. Another implementation is an array of capacitors, filled with and embedded within, elastic material. The structure linking the piezo “molecules” together need not be simply a homogenous elastic matrix. It can be discretely lined, or can have anisotropic elasticity, be an auxetic material, include mechanical metamaterials, etc.

In an embodiment, a piezoelectric material is made from polarized material that undergoes internal displacements, e.g., deformation of a polarized crystal, or polarized molecules that get shifted relative to each other. We can make an artificial piezo material on the mesa-scale; form a bunch of polarized structures linked together with elastic elements so that they can be displaced, changing the polarization. Displacements can change the length of each dipole moment, or the angle or spacing between neighboring dipoles. An advantage is that each dipole is large, so can hold a lot of charge, thereby having a large dipole moment; the counter, of course, is that the density of them is lower. Another crucial aspect is that the overall crystal symmetry has to be chosen properly; for many symmetry classes, effects will cancel out. Fortunately, since this is an artificial material, we can arrange it with the right symmetry; types that reinforce the interactions, not cancel them. In an implementation, each polarized “molecule” consists of a dielectric rod (with desired elasticity) and charged metal balls on each end. An array of such “molecules” is laid out, in a selected symmetry pattern. The space between “molecules” is filled with a dielectric, having desired elasticity. Another implementation is an array of capacitors, filled with and embedded within, elastic material. The structure linking the piezo “molecules” together need not be simply a homogenous elastic matrix. It can be discretely liked, or can have anisotropic elasticity, be an auxetic material, include mechanical metamaterials, etc.

All references cited herein are hereby incorporated by reference in their entirety or to the extent their subject matter is not otherwise inconsistent herewith.

In some embodiments, “configured” includes at least one of designed, set up, shaped, implemented, constructed, or adapted for at least one of a particular purpose, application, or function.

It will be understood that, in general, terms used herein, and especially in the appended claims, are generally intended as “open” terms. For example, the term “including” should be interpreted as “including but not limited to.” For example, the term “having” should be interpreted as “having at least.” For example, the term “has” should be interpreted as “having at least.” For example, the term “includes” should be interpreted as “includes but is not limited to,” etc. It will be further understood that if a specific number of an introduced claim recitation is intended, such an intent will be explicitly recited in the claim, and in the absence of such recitation no such intent is present. For example, as an aid to understanding, the following appended claims may contain usage of introductory phrases such as “at least one” or “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a receiver” should typically be interpreted to mean “at least one receiver”); the same holds true for the use of definite articles used to introduce claim recitations. In addition, even if a specific number of an introduced claim recitation is explicitly recited, it will be recognized that such recitation should typically be interpreted to mean at least the recited number (e.g., the bare recitation of “at least two chambers,” or “a plurality of chambers,” without other modifiers, typically means at least two chambers).

In those instances where a phrase such as “at least one of A, B, and C,” “at least one of A, B, or C,” or “an [item] selected from the group consisting of A, B, and C,” is used, in general such a construction is intended to be disjunctive (e.g., any of these phrases would include but not be limited to systems that have A alone, B alone, C alone, A and B together, A and C together, B and C together, or A, B, and C together, and may further include more than one of A, B, or C, such as A₁, A₂, and C together, A, B₁, B₂, C₁, and C₂ together, or B₁ and B₂ together). It will be further understood that virtually any disjunctive word or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

The herein described aspects depict different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality. Any two components capable of being so associated can also be viewed as being “operably couplable” to each other to achieve the desired functionality. Specific examples of operably couplable include but are not limited to physically mateable or physically interacting components or wirelessly interactable or wirelessly interacting components.

With respect to the appended claims the recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Use of “Start,” “End,” “Stop,” or the like blocks in the block diagrams is not intended to indicate a limitation on the beginning or end of any operations or functions in the diagram. Such flowcharts or diagrams may be incorporated into other flowcharts or diagrams where additional functions are performed before or after the functions shown in the diagrams of this application. Furthermore, terms like “responsive to,” “related to,” or other past-tense adjectives are generally not intended to exclude such variants, unless context dictates otherwise.

While various aspects and embodiments have been disclosed herein, other aspects and embodiments will be apparent to one skilled in the art. The various aspects and embodiments disclosed herein are for purposes of illustration and are not intended to be limiting, with the true scope and spirit being indicated by the following claims.

1. An apparatus comprising:
a base having a first surface;
an array of pillars, each pillar of the array of pillars includes:
(i) a first end attached to the first surface of the base;
(ii) a second end having an electric charge retention portion;
(iii) a physical separation from adjacent pillars of the array of pillars; and
(iv) an electrical conductor configured to electrically connect the electric charge retention portion with a bus structure;
wherein the bus structure is configured to addressably connect with the electrical conductor of each respective pillar of the array of pillars.

2. The apparatus of claim 1, wherein the base includes the bus structure.

3. (canceled)

4. The apparatus of claim 1, wherein the base includes a flexible base.

5. The apparatus of claim 1, wherein the base includes a flexible material wearable by or integratable into a fabric wearable by a human user.

6. (canceled)

7. The apparatus of claim 1, wherein the base includes an electronic substrate material.

8. The apparatus of claim 1, wherein the base includes a material structured to propagate surface acoustic waves.

9. The apparatus of claim 1, wherein the base includes a material structured to propagate bulk acoustic waves.

10. The apparatus of claim 1, wherein the base includes a second surface opposite the first surface and configured to reflect electromagnetic waves.

11. The apparatus of claim 1, wherein the array of pillars includes a patterned array of pillars.

12. The apparatus of claim 1, wherein the array of pillars includes the first ends of the pillars arranged on the first surface of the base in a two-dimensional pattern.

13. The apparatus of claim 1, wherein the array of pillars includes an arbitrarily array of pillars.

14. The apparatus of claim 1, wherein the array of pillars includes an array of flexible pillars.

15. The apparatus of claim 1, wherein the array of pillars includes an array of pillars each having a selected elasticity.

16-20. (canceled)

21. The apparatus of claim 1, wherein a spacing between the pillars of the array of pillars is constant distance.

22. The apparatus of claim 1, wherein a spacing between the pillars of the array of pillars includes a spatially variable spacing.

23. The apparatus of claim 1, wherein at least one pillar of the array of pillars has a first moment of inertia in a first direction and a second moment of inertia in a second direction.

24-27. (canceled)

28. The apparatus of claim 1, wherein at least one pillar of the array of pillars includes a cross-section that varies along its length.

29. The apparatus of claim 1, wherein at least one pillar of the array of pillars includes a cross-section that is larger at the first end than a cross-section at a second end.

30. The apparatus of claim 1, wherein at least one pillar of the array of pillars includes a cross-section that is larger than a cross-section of the first end and larger than a cross-section of the second end.

31. The apparatus of claim 1, wherein at least one pillar of the array of pillars has a lateral aspect ratio greater than 1:1.

32. The apparatus of claim 1, wherein at least one pillar of the array of pillars has a lateral aspect ratio greater than 10:1.

33-36. (canceled)

37. The apparatus of claim 1, wherein the array of pillars includes a first pillar having a first length and a second pillar having a second length greater than the first length.

38. The apparatus of claim 1, wherein the array of pillars includes at least two pillars formed using a nanosphere lithography.

39. The apparatus of claim 1, wherein the array of pillars includes an array of dielectric pillars.

40. The apparatus of claim 1, wherein each pillar of the array of pillars includes an electrical insulator portion separating the electric charge retention portion from the first end of the pillar.

41. The apparatus of claim 1, wherein the array of pillars includes at least two dielectric pillars each having a relative permittivity greater than 3.

42. The apparatus of claim 1, wherein the array of pillars includes at least two dielectric pillars each having a relative permittivity greater than 11.

43-44. (canceled)

45. The apparatus of claim 1, wherein each pillar of the array of pillars further includes:
(v) a flexible mid-portion located between the first end and the second end of the pillar.

46. The apparatus of claim 1, wherein each pillar of the array of pillars further includes:
(v) a rigid mid-portion located between the first end and the second end of the pillar.

47. The apparatus of claim 1, wherein the electric charge retention portion of at least one pillar of the array of pillar includes two separate electric charge retention portions carried on respective opposing sides of the pillar.

48. The apparatus of claim 1, wherein the electric charge retention portion of at least one pillar of the array of pillars includes an electrically conductive cap.

49. The apparatus of claim 1, wherein the physical separation includes an electrical separation from adjacent pillars of the array of pillars.

50. The apparatus of claim 1, wherein the physical separation includes an air or dielectric-filled gap separation from adjacent pillars of the array of pillars.

51. The apparatus of claim 1, wherein the electric charge retention portion of at least one pillar of the array of pillars includes a permanently magnetic portion.

52-54. (canceled)

55. The apparatus of claim 1, wherein the electrical conductor of at least one pillar of the array of pillars is electrically connected to the bus structure by an electric switching circuit.

56. The apparatus of claim 1, wherein the base includes an electrically conductive plane.

57. The apparatus of claim 56, wherein the electrically conductive plane includes a first electrically conductive plane located electromagnetically proximate to a first group of pillars of the array of pillars and a second electrically conductive plane located electromagnetically proximate to a second group of pillars of the array of pillars.

58. The apparatus of claim 56, wherein the first surface of the base includes the electrically conductive plane.

59-72. (canceled)

73. A method comprising:
receiving an electrical signal;
selecting voltages of an electric charge retention portion of each respective pillar of an array of pillars to create in an acoustic wave propagation medium an acoustic wave representative of the received electrical signal, the array of pillars each having a respective a first end attached to a first surface of a base coupled with an acoustic wave propagation medium and a second end having the electric charge retention portion; and
applying the selected voltage to the electric charge retention portion of respective each pillar of the array of pillars.

74. The method of claim 73, wherein the applying includes applying the selected voltage to the electric charge retention portion of each respective pillar of the array of pillars using a bus structure configured to addressably connect with an electrical conductor of each respective pillar of the array of pillars.

75. The method of claim 73, wherein the applying includes applying the selected voltage to the electric charge retention portion of each respective pillar of the array of pillars using bus structure configured to addressably connect with an electrical conductor of each respective pillar of the array of pillars and an electrically conductive plane associated with the base.

76. The method of claim 73, wherein the selecting includes selecting based on a library of at least two shape or stiffness configurations the voltages of an electric charge retention portion of each respective pillar of the array of pillars to create an acoustic wave in the acoustic wave propagation medium representative of the received electrical signal.

77. The method of claim 73, wherein the selecting includes selecting by computation-on-the-fly the voltages of an electric charge retention portion of each respective pillar of the array of pillars to create an acoustic wave in the acoustic wave propagation medium representative of the received electrical signal.

78-149. (canceled)
